(19) United States
(12) Patent Application Publication
(10) Pub. No.: US 2025/0054747 A1
(43) Pub. Date: Feb. 13, 2025

(54) CONFORMAL DEPOSITION OF SILICON NITRIDE

(71) Applicant: Lam Research Corporation, Fremont, CA (US)

(72) Inventors: Awnish Gupta, Hillsboro, OR (US); Bart J. Van Schravendijk, Palo Alto, CA (US); Dustin Zachary Austin, Tigard, OR (US); Frank Loren Pasquale, Tigard, OR (US)

(21) Appl. No.: 18/717,975

(22) PCT Filed: Dec. 1, 2022
(86) PCT No.: PCT/US2022/080732

§ 371 Date: Jun. 7, 2024

Related U.S. Application Data
(60) Provisional application No. 63/265,405, filed on Dec. 14, 2021.

(51) Int. Cl. H01L 21/02; C23C 16/455; H01L 21/027; H01L 21/768

(52) U.S. Cl. CPC H01L 21/0217; C23C 16/45542; C23C 16/45553; H01L 21/02211; H01L 21/02274; H01L 21/0228; H01L 21/02318; H01L 21/76831; H01L 21/0274

(57) ABSTRACT

High quality silicon nitride (silicon nitride characterized by low wet etch rate in dilute hydrofluoric acid) is deposited on a semiconductor substrate having one or more recessed features in a highly conformal manner. The deposition involves exposing the semiconductor substrate to a silicon-containing precursor (e.g., an aminosilane) to form an adsorbed layer of the silicon-containing precursor on the substrate. The adsorbed layer is then treated with a plasma formed in a process gas that includes N₂, at a temperature of 300-750° C. and a pressure of at least about 15 Torr (e.g., 15-30 Torr) to convert the precursor to silicon nitride. The exposure to precursor and conversion to silicon nitride are repeated in the same process chamber over many deposition cycles until a conformal silicon nitride of desired thickness is formed. In some embodiments the deposited films are hydrogen-free as evidenced by IR spectra.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety.

### FIELD OF THE INVENTION

This invention pertains to methods and apparatuses for semiconductor device manufacturing. Specifically, embodiments of this invention pertain to methods and apparatuses for conformal deposition of silicon nitride in semiconductor processing.

### BACKGROUND

In semiconductor device fabrication, deposition and etching techniques are used for forming patterns of materials, such as for forming metal lines embedded in dielectric layers. Deposition techniques include atomic layer deposition (ALD), chemical vapor deposition (CVD), and physical vapor deposition (PVD). Etching techniques include wet etching methods and dry etching methods, such as reactive ion etching (RIE).

ALD is usually a preferred deposition technique when conformal deposition of material is needed, because ALD relies on adsorption of one or more reactants, and typically uses surface-limited reactions, thereby minimizing thickness variation in deposited layers.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

High quality silicon nitride (silicon nitride having low wet etch rate (WER) in dilute hydrofluoric acid) is difficult to deposit in a conformal manner. Methods and apparatuses for deposition of silicon nitride are provided. In some embodiments provided methods allow for deposition of silicon nitride in recessed features in a highly conformal manner (e.g., with conformality of at least about 80%, such as at least about 90%, or at least about 95%), where the deposited silicon nitride is characterized by low wet etch rate in 100:1 (H₂O:HF) dilute aqueous hydrofluoric acid (e.g., with WER of less than about 3 Å/minute, such as less than about 2 Å/minute). In some embodiments provided methods allow for conformal deposition of substantially hydrogen-free silicon nitride as evidenced by absence of Si—H and N—H peaks in IR spectra. Provided methods can be used for deposition of silicon nitride liners in high aspect ratio recessed features, such as in recessed features with aspect ratios of at least about 5:1, at least about 10:1, or at least about 50:1.

In one aspect, a method of depositing a silicon nitride layer on a semiconductor substrate is provided. The method involves: (a) in a deposition process chamber, exposing the semiconductor substrate to a silicon-containing precursor, wherein the silicon-containing precursor further includes at least one nitrogen (N) atom, to form an adsorbed layer of the silicon-containing precursor on the semiconductor substrate; and (b) in the same process chamber, treating the semiconductor substrate with a plasma formed in a process gas comprising nitrogen (N₂) to convert the adsorbed layer of the silicon-containing precursor to silicon nitride, wherein the conversion of the adsorbed layer of the silicon-containing precursor to silicon nitride is performed at a temperature of between about 300 and about 750° C. and a pressure of at least about 15 Torr. In some embodiments the silicon-containing precursor is a halogen-free silicon-containing precursor.

In some embodiments the substrate includes at least one recessed feature, and the silicon nitride layer is deposited in the recessed feature with a conformality of at least about 80%. Additionally, the silicon nitride layer deposited in the recessed feature with a conformality of at least about 80% may have a wet etch rate (WER) in 100:1 hydrofluoric acid of less than about 3 Å/minute. For example, in some embodiments the silicon nitride layer is deposited in the recessed feature with a conformality of at least 90%, and the deposited silicon nitride has a wet etch rate (WER) in 100:1 hydrofluoric acid of less than about 2 Å/minute.

In some embodiments the conversion of the adsorbed layer of the silicon-containing precursor to silicon nitride is performed at a temperature of between about 400 and about 750° C. and a pressure of between about 15 and about 30 Torr.

In some embodiments the process gas used in the conversion step further includes a noble gas (e.g. argon), and N₂ content in the process gas is less than about 10% by volume, such as less than about 5% by volume.

In some embodiments the silicon nitride deposition includes at least 100 deposition cycles, where each cycle includes one silicon-containing precursor exposure step (a) and one plasma conversion step (b). In some embodiments the process chamber is purged to remove the unadsorbed silicon-containing precursor after the silicon-containing exposure step (a).

In some embodiments, the semiconductor substrate includes a recessed feature with an aspect ratio of at least 5:1, and the silicon nitride is deposited in the recessed feature conformally to a thickness of at least 100 Å.

In some embodiments the method involves repeating exposure and conversion steps (a)-(b) to form the completed silicon nitride layer of a desired thickness; and annealing the completed silicon nitride layer by exposing the semiconductor substrate to N₂ in an absence of plasma at a temperature of at least 700° C., where the annealing reduces absolute value of stress of silicon nitride.

Examples of suitable silicon-containing halogen-free precursors that include nitrogen include without limitation aminosilanes, such as di(methylamino)silane (DMAS), di(ethylamino)silane (DEAS), di(propylamino)silane (DPAS), di(isopropylamino)silane (DIPAS), di(sec-butylamino)silane (DSBAS), bis-(t-butylamino)silane (BTBAS), and tris(dimethylamino)silane (TDMAS).

In some embodiments the methods provided herein are integrated with photolithographic processing. For example, the methods may include the steps of: applying photoresist to the semiconductor substrate; exposing the photoresist to light; patterning the photoresist and transferring the pattern to the semiconductor substrate; and selectively removing the photoresist from the semiconductor substrate. For example, such photolithographic patterning may be used to form recessed features on the substrate prior to silicon nitride deposition.

In another aspect an apparatus for processing a semiconductor substrate is provided. In some embodiments the apparatus includes a process chamber configured for housing the substrate, where the process chamber includes a substrate holder configured to hold the substrate and an inlet configured to introduce one or more reactants to the process chamber. The apparatus further includes a mechanism for generating a plasma and a controller having program instructions configured to cause performance of the steps of any of the methods provided herein. For example, the controller may include program instructions configured to effect deposition of a silicon nitride layer on the semiconductor substrate by causing: (i) in the deposition process chamber, exposing the semiconductor substrate to a halogen-free silicon-containing precursor, wherein the silicon-containing precursor further includes at least one nitrogen (N) atom, to form an adsorbed layer of the silicon-containing precursor on the semiconductor substrate; and (ii) in the same process chamber, treating the semiconductor substrate with a plasma formed in a process gas comprising nitrogen (N₂) to convert the adsorbed layer of the silicon-containing precursor to silicon nitride, wherein the conversion of the adsorbed layer of the silicon-containing precursor to silicon nitride is performed at a temperature of between about 300 and about 750° C. (e.g., between about 400 and about 750° C.) and a pressure of at least about 15 Torr (e.g., between about 15 and about 30 Torr). The controller may further include program instructions for causing repetition of steps (i) and (ii) to perform at least 100 deposition cycles. The program instructions, in some embodiments are configured to cause exposure of the semicondutor substrate to a halogen-free silicon-containing precursor that is an aminosilane selected from the group consisting of di(methylamino)silane (DMAS), di(ethylamino)silane (DEAS), di(propylamino)silane (DPAS), di(isopropylamino)silane (DIPAS), di(sec-butylamino)silane (DSBAS), bis-(t-butylamino)silane (BTBAS), and tris(dimethylamino)silane (TDMAS).

In some embodiments the program instructions are configured to cause conformal deposition of the silicon nitride in a recessed feature with a conformality of at least about 80%.

In another aspect a system is provided, wherein the system includes a deposition apparatus provided herein and a stepper.

In another aspect, a non-transitory computer machine-readable medium is provided, wherein the computer machine-readable medium includes program instructions for control of an apparatus configured for semiconductor substrate processing, wherein the program instructions comprise code configured to effect: (i) in a deposition process chamber, an exposure of the semiconductor substrate to a halogen-free silicon-containing precursor, wherein the silicon-containing precursor further includes at least one nitrogen (N) atom, to form an adsorbed layer of the silicon-containing precursor on the semiconductor substrate; and (ii) in the same process chamber, a treatment of the semiconductor substrate with a plasma formed in a process gas comprising nitrogen (N₂) to convert the adsorbed layer of the silicon-containing precursor to silicon nitride, wherein the conversion of the adsorbed layer of the silicon-containing precursor to silicon nitride is performed at a temperature of between about 300 and about 750° C. and a pressure of at least about 15 Torr.

In another aspect, a method of depositing a silicon nitride layer on a semiconductor substrate is provided, where the method includes: (a) in a deposition process chamber, exposing the semiconductor substrate to a halogen-free silicon-containing precursor, wherein the silicon-containing precursor further includes nitrogen (N), to form an adsorbed layer of the silicon-containing precursor on the semiconductor substrate; and (b) in the same process chamber, treating the semiconductor substrate with a plasma formed in a process gas comprising nitrogen (N₂) to convert the adsorbed layer of the silicon-containing precursor to silicon nitride, wherein the conversion of the adsorbed layer of the silicon-containing precursor to silicon nitride is performed at a temperature of between about 300 and about 750° C. and wherein the content of N₂ in the process gas is less than about 10%.

These and other aspects of implementations of the subject matter described in this specification are set forth in the accompanying drawings and the description below.

### BRIEF DESCRIPTION OF THE DRAWINGS

FIG. 1A is a schematic cross-sectional presentation of a substrate having a recessed feature before deposition of silicon nitride.

FIG. 1B is a schematic cross-sectional presentation of a substrate having a recessed feature after deposition of silicon nitride with low conformality.

FIG. 1C is a schematic cross-sectional presentation of a substrate having a recessed feature after deposition of silicon nitride with high conformality according to an embodiment provided herein.

FIG. 2 is a process flow diagram for a silicon nitride deposition method according to an embodiment provided herein.

FIG. 3 is a timing diagram for a silicon nitride deposition method according to an embodiment provided herein.

FIG. 4 is a schematic presentation of an apparatus that is suitable for depositing silicon nitride, according to an embodiment provided herein.

FIG. 5 is a schematic presentation of a system that is suitable for depositing silicon nitride, according to an embodiment provided herein.

FIG. 6 is an experimental plot illustrating sidewall thicknesses of deposited silicon nitride at different feature depths.

FIG. 7 is an experimental plot illustrating sidewall thickness of deposited silicon nitride and WER at different feature depths.

FIG. 8 is an experimental plot illustrating silicon nitride step coverage as a function of feature depth for different deposition conditions.

FIG. 9 is an experimental plot illustrating stress reduction of deposited silicon nitride films after an anneal.

### DETAILED DESCRIPTION OF THE PREFERRED EMBODIMENTS

Methods and apparatuses for deposition of silicon nitride are provided. Provided methods can be used in a variety of applications but are particularly useful for deposition of conformal high quality silicon nitride layers on semiconductor substrates that have high aspect ratio recessed features, such as recessed features with aspect ratios of at least about 5:1, at least about 10:1, at least about 50:1, or at least about 100:1. Silicon nitride can be deposited conformally such that it covers the sidewalls and bottom portions of the recessed features on a variety of materials, including but not limited to silicon (amorphous or polycrystalline), silicon germanium, silicon oxide, silicon carbide, metal oxides, etc. In one implementation, silicon nitride is deposited conformally over silicon fins in FinFET fabrication. The deposited silicon nitride layers can function as liners, etch stop layers, charge trap layers for memory devices, etc. In some embodiments the deposited silicon nitride is used in complete gapfill, e.g., recessed feature is completely filled with silicon nitride after multiple conformal depositions. In some embodiments, the conformally deposited silicon nitride that lines sidewalls and bottom portion of a recessed feature is characterized by WER of less than about 5 Å/minute, such as less than 3 Å/minute, or less than about 2 Å/minute at all locations of the recessed feature.

The term “wet etch rate” (WER) as used herein refers to an etch rate in 100:1 (H₂O:HF) dilute hydrofluoric acid. Dilute hydrofluoric acid is obtained by diluting 49% (weight %) aqueous hydrofluoric acid with water (100 parts of water per 1 part of 49% HF).

The term “conformality” as used herein refers to a measure of thickness variation on a sidewall of a recessed feature and is determined as a ratio of a film thickness on a sidewall of a recessed feature at a feature depth that is 90% of the recessed feature's total depth to a film thickness on a sidewall of a recessed feature at a feature depth that is 10% of the recessed feature's total depth, expressed in percent. For example, if the depth of the recessed feature is 100 nm, and the thickness of the deposited silicon nitride on a sidewall is 50 Å at a feature depth of 10 nm, and is 40 Å at a feature depth of 90 nm, the conformality of deposited film is 40/50 multiplied by 100% and is equal to 80%.

The term “high quality silicon nitride” as used herein refers to silicon nitride that has a WER of less than about 3 Å/minute. In some embodiments the high quality silicon nitride is substantially hydrogen-free, as evidenced by absence of Si—H and N—H peaks on IR spectra at about 2200 cm⁻¹ and about 3300 cm⁻¹ respectively.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The semiconductor wafer may be of various shapes, sizes, and materials. In addition to semiconductor wafers, other types of work pieces may take advantage of the disclosed implementations including various articles such as printed circuit boards and the like.

The term “about” when used in reference to numerical values includes a range of ±10% of the recited numerical value, unless otherwise specified.

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (11) C₁₋₆ aminoalkyl (e.g., -L¹-NR¹R² or -L²—C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

Deposition of high quality silicon nitride in a conformal manner is a challenging problem. While silicon nitride films with this combination of properties can be obtained at a very high temperature of above 850° C. in a furnace deposition, it was not possible to attain such films at lower temperatures in plasma-enhanced deposition processes. Specifically, the quality of silicon nitride deposited using lower temperature plasma-enhanced processes, inversely correlates with conformality. For example, silicon nitride films that have WER of less than 3 Å could not be deposited with high conformality using conventional plasma-enhanced deposition methods. Further, silicon nitride films that have high conformality of at least about 80%, when deposited by conventional plasma-enhanced methods, typically have low quality and are characterized by high WER.

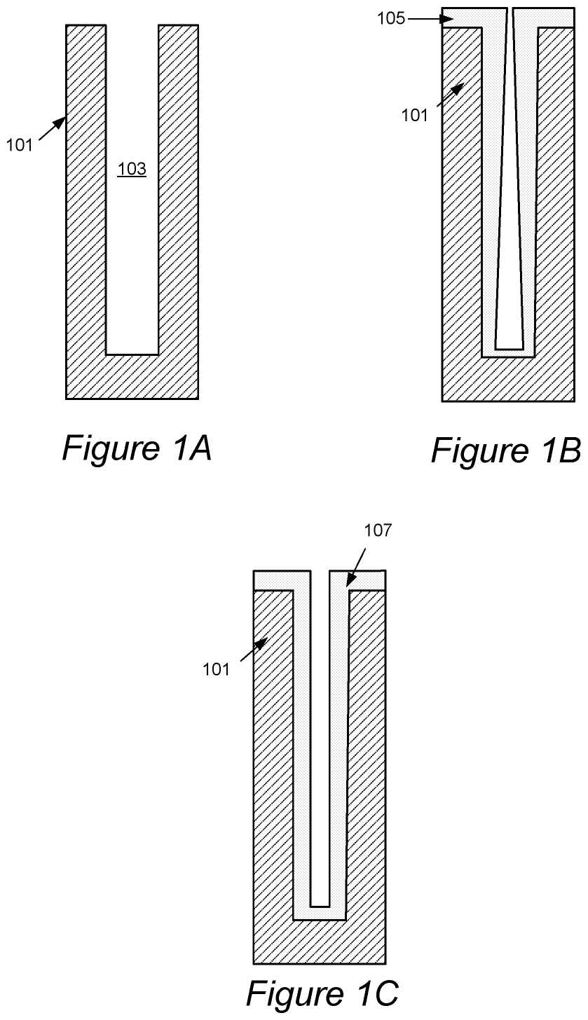

Deposition with low conformality is illustrated by FIGS. 1A and 1B. FIGS. 1A and 1B illustrate schematic cross-sectional views of a semiconductor substrate 101 having a recessed feature 103 before silicon nitride deposition (FIG. 1A) and after silicon nitride deposition with low conformality (FIG. 1). It can be seen that silicon nitride layer 105 in FIG. 1B covers the sidewalls of the recessed feature 103 such that there is high thickness variation, with a thicker silicon nitride layer being deposited near the opening of the recessed feature, and much thinner coverage at deeper portions of the recessed feature.

Provided methods address this problem and allow for deposition of high quality silicon nitride in a conformal manner at temperatures of less than about 800° C. Specifically, high quality silicon nitride can be deposited conformally on a semiconductor substrate having recessed features at temperatures of between about 300-750° C. In some embodiments provided methods can be used to deposit silicon nitride on a semiconductor substrate having recessed features with a conformality of at least about 80%, such as at least about 90%, or at least about 95%. For example, silicon nitride films characterized by WER of less than about 3 Å/minute can be deposited with conformality of at least about 80%. In some embodiments, silicon nitride films characterized by WER of less than about 2 Å/minute are deposited with conformality of at least about 90%. It is understood that provided methods are not limited by these advantages, and can be used, for example, for deposition of silicon nitride as a blanket layer on a substrate without recessed features. Further, while these methods are particularly useful for deposition in recessed features with aspect ratios of at least about 5:1, such as at least about 10:1, it is understood that these methods can be also used for silicon nitride deposition in features with lower aspect ratios.

The provided methods involve the steps of exposing the semiconductor substrate to a silicon-containing precursor to allow the silicon-containing precursor to adsorb to the semiconductor substrate, followed by treating the semiconductor substrate with a plasma formed in a process gas, where the process gas includes N₂, to convert the adsorbed silicon-containing precursor to silicon nitride (conversion step). The conversion is carried out at a temperature of between about 300-750° C. It was unexpectedly discovered that conformality is significantly increased when pressure during the plasma conversion step is raised to at least about 15 Torr as compared to lower pressures. This discovery was unexpected because one would expect that lower pressure would lead to greater mean free path of nitrogen-containing species in a plasma thus allowing nitrogen to reach deep into the recessed features, and thereby resulting in increased deposition near the bottom of the recessed features and better conformality. Contrary to this expected result, pressures of at least about 15 Torr have shown to provide significantly more conformal deposition as compared to lower pressures (e.g., 2 Torr), without significant reduction in silicon nitride quality. Thus, in some embodiments, the treatment of the semiconductor substrate with a plasma formed in a process gas that includes N₂, is conducted at a pressure of at least 15 Torr, more preferably between about 15-30 Torr. The resulting conformally deposited silicon nitride layer 107 is shown in FIG. 1C.

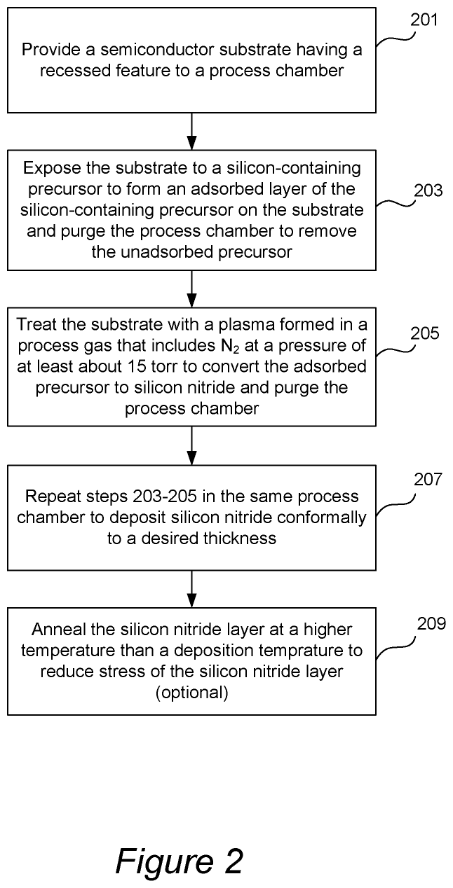

FIG. 2 illustrates a process flow diagram for an embodiment of the provided method. The process starts in step 201 by providing the semiconductor substrate having a recessed feature, such as a substrate illustrated in FIG. 1A, to a process chamber. Next, in step 203 the semiconductor substrate is exposed to a silicon-containing precursor to form an adsorbed layer of the precursor on the substrate, and then the process chamber is purged to remove the unadsorbed precursor. In some embodiments, the silicon-containing precursor is a nitrogen-containing halogen-free precursor. Preferably, the precursor is an aminosilane or another compound that includes a silicon-nitrogen bond. Examples of such precursors include without limitation di(methylamino)silane (DMAS), di(ethylamino)silane (DEAS), di(propylamino)silane (DPAS), di(isopropylamino)silane (DIPAS), di(sec-butylamino)silane (DSBAS), bis-(t-butylamino)silane (BTBAS), and tris(dimethylamino)silane (TDMAS).

Next, in step 205 the substrate is treated with a plasma formed in a process gas that includes N₂, at a pressure of at least about 15 torr to convert the adsorbed precursor to silicon nitride, and the process chamber is purged. In some embodiments this conversion step is performed at a pressure of between about 15-30 torr. It was unexpectedly discovered that conformality of silicon nitride deposition can be further improved by using a process gas during conversion step with a relatively low content of nitrogen. In some embodiments the process gas has N₂ content of about 10% or less by volume such as less than about 5% by volume. For example, the process gas may include N₂ and a noble gas (e.g., argon, helium, or neon), where N₂ content is less than about 10% by volume, or less than about 5% by volume. In some implementations the N₂ content is between about 1-10%. The improvement of conformality with the use of relatively low content of N₂ (which also translates to lower partial pressure of N₂) was unexpected, because one would expect that increased content of N₂ will result in higher reactivity throughout the recessed feature and more conformal conversion of the precursor to silicon nitride. Contrary to this expectation, it was observed that conformality was improved when nitrogen content in the process gas was lowered to 10% or less in the plasma treatment step. It is noted that the provided deposition methods are not limited to low nitrogen content embodiments, and that higher nitrogen content, such as 15-100% N₂ is also within the scope of the provided embodiments.

The plasma formed in the process gas may be formed in the process chamber housing the semiconductor substrate (direct plasma), or away from the chamber housing the semiconductor substrate (remote plasma) which is then be delivered to the process chamber housing the substrate In some embodiments capacitively coupled plasma is generated using a RF frequency of 13.56 MHz or 27 MHz. The power used for plasma generation may range in some embodiments from about 500 W to about 10,000 W with power density ranging from 0.177 W/cm² to 3.54 kW/cm², where cm² refer to substrate area.

Steps 203-205 constitute one deposition cycle. In some embodiments the temperature for all steps of the deposition cycle is maintained at between about 300-750° C., such as between about 400-750° C., or about 600-700° C., and the pressure is maintained to be at least about 15 Torr, such as between about 15-30 Torr. In some embodiments the temperature and pressure during precursor adsorption step 203 and conversion step 205 is substantially the same. In other embodiment, the pressure and/or temperature for steps 203 and 205 may be different. A single cycle deposits in some embodiments between about 0.5-2 Å on average.

In the next step 207, the steps 203-205 are repeated in the same process chamber to deposit the silicon nitride to a desired thickness. In various implementations at least 10, such as at least 100, for example 100-2,000 deposition cycles are performed to deposit the silicon nitride film, where the resulting film thickness may be, for example between about 5 and about 100 nm. Deposition may be conducted in recessed features of various depths, with depths, in some examples reaching 10 micron or more.

Optionally, after deposition of the silicon nitride film, in step 209, the film may be annealed at a higher temperature to reduce stress of the silicon nitride film and/or to further reduce WER. For example, steps 203-207 me be carried out at a temperature of between about 600-650° C., and the anneal may be conducted at a higher temperature (e.g., at 700-750° C.) while exposing the semiconductor substrate to N₂. In some embodiments, the anneal is carried out for a fairly prolonged time (e.g., 10 minutes or more) in a process chamber that is different from the deposition process chamber where steps 201-207 are conducted.

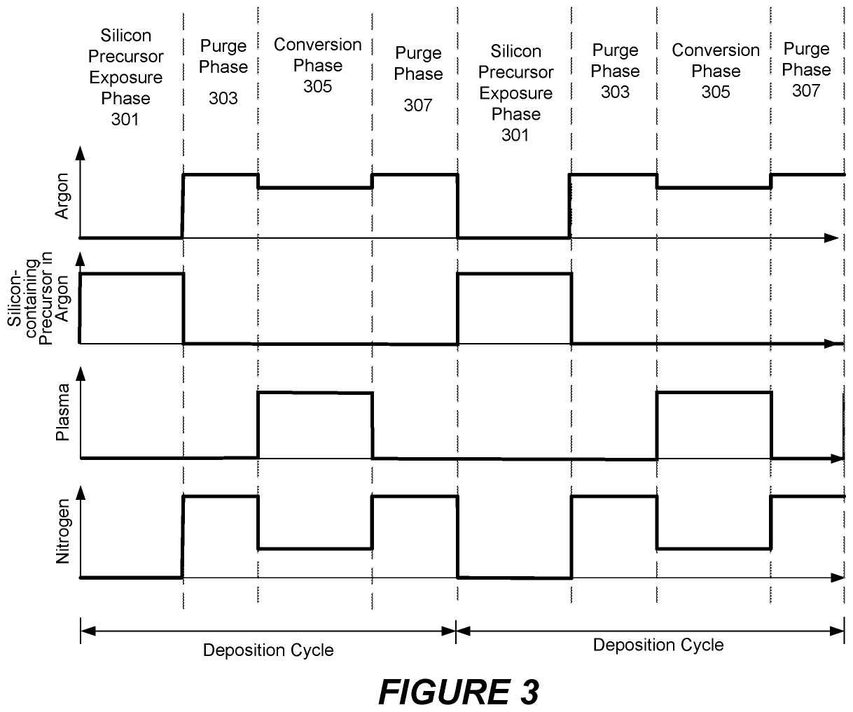

FIG. 3 shows an illustrative timing diagram for two deposition cycles of a silicon nitride deposition process, according to an embodiment provided herein. In the silicon precursor exposure phase 301, the semiconductor substrate is exposed to the silicon-containing precursor (delivered to the process chamber pre-mixed with argon push gas) in an absence of plasma. In other embodiments, the push gas may include N₂, or a mixture of argon and N₂. In some embodiments the flow rate of the silicon-containing precursor is between about 100-2,000 sccm, and the flow rate of the push gas is between about 300-1,500 sccm. In the depicted example, during the silicon precursor exposure phase 301, nitrogen is not flowed into the process chamber. In other embodiments N₂ may be flowed at a flow rate of 500-2,000 sccm for dilution and/or pressure stability. The pressure during this step is maintained at between about 1-30 Torr. The silicon precursor exposure phase 301 in the depicted embodiment lasts between about 0.1-10 seconds. Next, in the purge phase 303 the silicon-containing precursor flow is discontinued, argon flow is started (or increased) and nitrogen flow is also started (or increased). In one implementation in the purge phase 303, the argon flow rate is about 20 slm, the nitrogen flow rate is about 20 slm, with pressure being maintained in the range of between about 0.5-30 Torr. After the purge phase 303, which lasts 0.1-10 seconds, the conversion phase 305 starts. During the conversion phase, the nitrogen flow rate is reduced to about 1,000-5,000 sccm, argon flow rate is adjusted to about 10-40 slm, and plasma generation is turned on using plasma generation conditions described above. The pressure during conversion phase is maintained in the range of between about 15-30 Torr. The conversion phase 305 in which the adsorbed precursor is converted to silicon nitride is conducted, in some embodiments, for the duration of between about 0.1-30 seconds. Next, the plasma is turned off, and the nitrogen flow is increased as the process follows with the purge phase 307. The process conditions for the purge phase 307 can be the same as for the purge phase 303. Next, the silicon-containing exposure phase 301, the purge phase 303, the conversion phase 305, and the purge phase 307 are repeated.

### Silicon-Containing Precursors

A variety of silicon-containing precursors (also referred to as silicon-containing reactants) can be used in silicon nitride deposition methods provided herein. In some embodiments, nitrogen-containing precursors such as aminosilanes, silyl amines and silazanes are used.

Aminosilanes A silicon-containing precursor in some embodiments can include one or more optionally substituted amino groups, thereby providing a non-limiting amino silane. In one embodiment, the precursor has a formula of (R′)₄₋ₓSi(NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″₂N)ₓ(R′)₃₋ₓSi-L-Si(R′)₃₋ₓ(NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl; each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R′ groups and amino groups (NR″2) attached to one or more silicon atoms.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The silicon-containing reactant can include at least one R′ group attached to the silicon atom. In one embodiment, the precursor has a formula of (R′)(H)₃₋ₓSi(NR″₂)ₓ, wherein R′ and R″ can be any described herein, and wherein x is 1, 2, or 3. In another embodiment, the precursor has a formula of (R′)(H)₂Si(NR″₂), wherein R′ and R″ can be any described herein. In one embodiment, the precursor has a formula of (R′)(H)Si(NR″₂)₂, wherein R′ and R″ can be any described herein. In another embodiment, the precursor has a formula of (R′)₂(H)Si(NR″₂), wherein R′ and R″ can be any described herein. In yet another embodiment, the precursor has a formula of (R′)₂Si(NR″₂)₂, wherein R′ and R″ can be any described herein. In one embodiment, the precursor has a formula of (R′)₃Si(NR″₂), wherein R′ and R″ can be any described herein.

The silicon-containing reactant can lack an R′ group attached to the silicon atom. In one embodiment, the precursor has a formula of (H)₄₋ₓSi(NR″₂)ₓ, wherein each R″ can independently be any described herein, and wherein x is 1, 2, 3, or 4. In another embodiment, the precursor has a formula of Si(NR″₂)ₓ, wherein each R″ can independently be any described herein. In particular embodiments, each R″ is, independently, aliphatic, heteroaliphatic, aromatic, or heteroaromatic.

The silicon-containing reactant can include one or more hydrogen atoms attached to the silicon atom. In one embodiment, the precursor has a formula of (H)₃Si(NR″₂) or (H)₂Si(NR″₂)₂ or (H)Si(NR″₂)₃, wherein each R″ can independently be any described herein. In particular embodiments, each R″ is, independently, aliphatic, heteroaliphatic, aromatic, heteroaromatic, or amino, in which any of these may be optionally substituted.

The silicon-containing reactant can include a heterocyclyl group having a nitrogen atom. In one embodiment, the formula has a formula of H₃Si-Het, in which Het is an optionally substituted heterocyclyl including at least one nitrogen atom. In particular embodiments, the precursor has a formula of

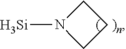

in which the heterocyclyl group can be optionally substituted (e.g., with any substituent described herein as a substitution for alkyl), and wherein n is 1, 2, 3, 4, or 5. In one embodiment, the formula has a formula of R′₃Si-Het, in which Het is an optionally substituted heterocyclyl including at least one nitrogen atom, and each R′ can independently be any described herein. In particular embodiments, the precursor has a formula of

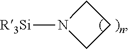

in which the heterocyclyl group can be optionally substituted (e.g., with any substituent described herein as a substitution for alkyl); each R′ can independently be any described herein; and wherein n is 1, 2, 3, 4, or 5.

In some instances, the silicon-containing reactant can have two or more silicon atoms, in which the precursor can include a Si—Si bond. In a particular embodiment, the precursor has a formula of (R″₂N)ₓ(R′)₃₋ₓSi—Si(R′)₃₋ₓ(NR″₂)ₓ, wherein R′ and R″ can be any described herein. In one embodiment, the silicon-containing reactant has a formula of (R″₂N)(R′)₂Si—Si(R′)₂(NR″₂), wherein R′ and R″ can be any described herein. In another embodiment, the silicon-containing reactant has a formula of (R″2N)₂(R′)Si—Si(R′)(NR″₂)₂, wherein R′ and R″ can be any described herein. In yet another embodiment, the silicon-containing reactant has a formula of (R″₂N)₃Si—Si(NR″₂)₃, wherein each R″ can independently be any described herein.

The silicon-containing reactant can include differing groups attached to the silicon atoms. In one instance, the precursor has a formula of (R″₂N)ₓ(R′)₃₋ₓSi—SiH₃, wherein R′ and R″ can be any described herein.

A linker can be present between two silicon atoms. In one instance, the silicon-containing reactant has a formula of (R″₂N)ₓ(R′)₃₋ₓSi—NR—Si(R′)₃₋ₓ(NR″₂)ₓ, wherein R′ and R″ can be any described herein, and in which R is H, optionally substituted aliphatic, optionally substituted alkyl, optionally substituted alkenyl, optionally substituted alkynyl, or optionally substituted aromatic. In another instance, the silicon-containing reactant has a formula of (R″₂N)ₓ(H)₃₋ₓSi—NR—Si(H)₃₋ₓ(NR″₂)ₓ, wherein R, R′, and R″ can be any described herein.

The silicon-containing reactant can include a combination of R′ groups with a linker having a heteroatom. In one instance, the silicon-containing reactant has a formula of (R′)₃Si—NR—Si(R′)₃, wherein R and R′ can be any described herein. In another instance, the precursor has a formula of (R′)₃Si-L-Si(R′)₃, wherein L and R′ can be any described herein. In particular embodiments, L is oxy (—O—), optionally substituted imino (e.g., —NR—), or optionally substituted silyl (e.g., —SiR₂—).

The silicon-containing reactant can include any useful combination of R′ and NR″₂ groups in combination with two silicon atoms. In one instance, the precursor has a formula of (R″2N)(R′)₂Si-L-Si(R′)₂(NR″₂)ₓ, wherein L, R′, and R″ can be any described herein.

The silicon-containing reactant can include heterocyclic groups including the silicon and nitrogen atoms. In one embodiment, the precursor has a formula of

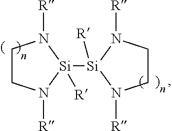

wherein R′ and R″ can be any described herein, and wherein n is 1, 2, 3, or 4.

In another embodiment, the silicon-containing reactant has a formula of

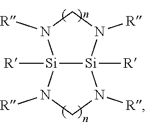

wherein R′ and R″ can be any described herein, and wherein n is 1, 2, 3, or 4. In yet another embodiment, the precursor has a formula of

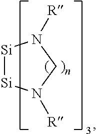

in which each R″ can independently be any described herein; and wherein n is 1, 2, 3, or 4.
In another embodiment, the silicon-containing reactant has a formula of

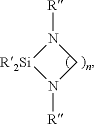

wherein R′ and R″ can be any described herein, and wherein n is 1, 2, 3, or 4. In yet another embodiment, the silicon-containing reactant has a formula of

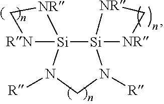

wherein R″ can independently be any described herein, and wherein n is 1, 2, 3, or 4.

In any silicon-containing reactant herein, two R″ can be taken together, with the nitrogen atom to which each is attached, to form an optionally substituted heterocyclyl.

Silicon-containing reactants can include any of the following, e.g., (R^{Ak})Si(NH₂)(NR^{Ak}₂)₂, (R^{Ak})Si(NR^{Ak}₂)₃, (R^{Ak})₂Si(NHR^{Ak}₂)₂, (R^{Ak})(H)Si(NHR^{Ak})₂, (R^{Ak})₃Si(NR^{Ak}₂), (R^{Ak})₃Si(NHR^{Ak}), H₂Si(NHR^{Ak}₂)₂, (R^{Ak})(H)Si(NR^{Ak}₂)₂, HSi(NH₂)(NR^{Ak}₂)₂, HSi(NR^{Ak}₂)₃, Si(NR^{Ak}₂)₄, (R′)(H)Si(NR″₂)₂, (R′)₂Si(NR^{Ak}₂)₂, (R′)₂Si(N[SiH₃]₂)₂, (R′)₂Si(N[SiR″₃]₂)₂, or (R′)₃Si(NHR^{Ak}). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R′ is, independently, H, optionally substituted aliphatic, optionally substituted heteroaliphatic, optionally substituted alkyl, optionally substituted alkenyl, or optionally substituted alkynyl. In particular embodiments, R^{Ak} is methyl (Me), ethyl (Et), n-propyl (nPr), iso-propyl (iPr), n-butyl (nBu), sec-butyl (sBu), iso-butyl (iBu), tert-butyl (tBu), and the like.

Non-limiting examples of silicon-containing reactant include any of the following: methylaminotrimethylsilane (SiMe₃[NHMe]); dimethylaminodimethylsilane (SiMe₂H[NMe₂]); dimethylaminotrimethylsilane (SiMe₃[NMe₂]); dimethylaminodiethylsilane (SiHEt₂[NMe₂]); dimethylaminotriethylsilane (SiEt₃[NMe₂]); ethylmethylaminodimethylsilane (SiHMe₂[NMeEt]); ethylmethylaminotrimethylsilane (SiMe₃[NMeEt]); ethylmethylaminodiethylsilane (SiHEt₂[NMeEt]); ethylmethylaminotriethylsilane (SiEt₃[NMeEt]); diethylaminomethylsilane (SiH₂Me[NEt₂]); diethylaminoethylsilane (SiH₂Et[NEt₂]); ethylaminotrimethylsilane (SiMe₃[NHEt]); diethylaminodimethylsilane (SiHMe₂[NEt₂]); diethylaminodiethylsilane (SiHEt₂[NEt₂]); diethylaminotrimethylsilane (SiMe₃[NEt₂]); diethylaminotriethylsilane (SiEt₃[NEt₂]); iso-propylaminodimethylsilane (SiHMe₂[NHiPr]); iso-propylaminotrimethylsilane (SiMe₃[NHiPr]); iso-propylaminodiethylsilane (SiHEt₂[NHiPr]); iso-propylaminotriethylsilane (SiEt₃[NHiPr]); di-isopropylaminotrimethylsilane (SiMe₃[NiPr₂]); di-iso-propylaminosilane (SiH₃[NiPr₂], C₆H₁₇NSi, or DIPAS); di-iso-propylaminomethylsilane (SiH₂Me[NiPr₂]); di-isopropylaminodimethylsilane (SiHMe₂[NiPr₂]); di-isopropylaminodiethylsilane (SiHEt₂[NiPr₂]); di-isopropylaminotriethylsilane (SiEt₃[NiPr₂]); n-propylaminotrimethylsilane (SiMe₃[NHnPr]); di-sec-butylaminosilane (SiH₃[NsBu₂] or DSBAS); di-sec-butylaminomethylsilane (SiH₂Me[NsBu₂]); iso-butylaminotrimethylsilane (SiMe₃[NHiBu]); n-butylaminotrimethylsilane (SiMe₃[NHnBu]); tert-butylaminodimethylsilane (SiHMe₂[NHtBu]); tert-butylaminotrimethylsilane (SiMe₃[NHtBu]); tert-butylaminodiethylsilane (SiHEt₂[NHtBu]); tert-butylaminotriethylsilane (SiEt₃[NHtBu]); dicyclohexylaminosilane (SiH₃[NCy₂], in which Cy is cyclohexyl); N-propylisopropylaminosilane (SiH₃[NiPrnPr]); N-methylcyclohexylaminosilane (SiH₃[NMeCy]); N-ethylcyclohexylaminosilane (SiH₃[NEtCy]); allylphenylaminosilane (SiH₃[NAllPh]); N-isopropylcyclohexylaminosilane (SiH₃[NiPrCy]); allylcyclopentylaminosilane (SiH₃[NAllCp]); phenylcyclohexylaminosilane (SiH₃[NPhCy]); cyclohexylaminotrimethylsilane (SiMe₃[NHCy], in which Cy is cyclohexyl); pyrrolyltrimethylsilane (SiMe₃[NHPy], in which Py is pyrrolyl); pyrrolidinotrimethylsilane (SiMe₃[NHPyr], in which Pyr is pyrrolidinyl); piperidino trimethylsilane (SiMe₃[NHPip], in which Pip is piperidinyl); piperazinotrimethylsilane (SiMe₃[NHPz], in which Pz is piperazinyl); imidazolyltrimethylsilane (SiMe₃[NHIm], in which Im is imidazolyl); bis(dimethylamino)silane (SiH₂[NMe₂]₂ or BDMAS); bis(dimethylamino) methylsilane (SiMeH[NMe₂]₂); bis(dimethylamino)dimethylsilane (SiMe₂[NMe₂]₂ or BDMADMS); bis(dimethylamino)diethylsilane (SiEt₂[NMe₂]₂); bis(dimethylamino) methylvinylsilane (SiMeVi[NMe₂]₂); bis(ethylamino)dimethylsilane (SiMe₂[NHEt]₂); bis(ethylmethylamino)silane (SiH₂[NMeEt]₂); bis(ethylmethylamino)dimethylsilane (SiMe₂[NMeEt]₂); bis(ethylmethylamino)diethylsilane (SiEt₂[NMeEt]₂); bis(ethylmethylamino) methylvinylsilane (SiMeVi[NMeEt]₂); bis(diethylamino)silane (SiH₂[NEt₂]₂, C₈H₂₂N₂Si, or BDEAS); bis(diethylamino)dimethylsilane (SiMe₂[NEt₂]₂); bis(diethylamino)methylvinylsilane (SiMeVi[NEt₂]₂); bis(diethylamino)diethylsilane (SiEt₂[NEt₂]₂); bis(iso-propylamino) dimethylsilane (SiMe₂[NHiPr]₂); bis(iso-propylamino)diethylsilane (SiEt₂[NHiPr]₂); bis(iso-propylamino)methylvinylsilane (SiMeVi[NHiPr]₂); bis(di-iso-propylamino)silane (SiH₂[NiPr₂]₂); bis(di-iso-propylamino)dimethylsilane (SiMe₂[NiPr₂]₂); bis(di-iso-propylamino) diethylsilane (SiEt₂[NiPr₂]₂); bis(di-iso-propylamino)methylvinylsilane (SiMeVi[NiPr₂]₂); bis(methylamino)silane (SiH₂[NHMe]₂); bis(sec-butylamino)silane (SiH₂[NHsBu]₂); bis(sec-butylamino)methylsilane (SiHMe[NHsBu]₂); bis(sec-butylamino)ethylsilane (SiHEt[NHsBu]₂); bis(tert-butylamino)silane (SiH₂[NHtBu]₂ or BTBAS); bis(tert-butylamino)dimethylsilane (SiMe₂[NHtBu]₂); bis(tert-butylamino) methylvinylsilane (SiMeVi[NHtBu]₂); bis(tert-butylamino)diethylsilane (SiEt₂[NHtBu]₂); bis(1-imidazolyl)dimethylsilane (SiMe₂[Im]₂, in which Im is imidazolyl); tris(dimethylamino)silane (SiH[NMe₂]₃ or 3DMAS); tris(dimethylamino)phenylsilane (SiPh[NMe₂]₃); tris(dimethylamino) methylsilane (SiMe[NMe₂]₃); tris(dimethylamino)ethylsilane (SiEt[NMe₂]₃); tris(ethylmethylamino)silane (SiH[NEtMe]₃); tris(diethylamino)silane (SiH[NEt₂]₃); tris(iso-propylamino)silane (SiH[NHiPr]₃, C₉H₂₅N₃Si, or TIPAS); tris(dimethylamino)silylamide (Si[NMe₂]₃[NH₂]); tetrakis(dimethylamino)silane (Si[NMe₂]₄); tetrakis(ethylmethylamino)silane (Si[NEtMe]₄); tetrakis(diethylamino)silane (Si[NEt₂]₄); 1,2-diethyl-tetrakis(diethylamino) disilane ([Et₂N]₂EtSi-SiEt[NEt₂]₂); 1,2-dimethyl-tetrakis(dimethylamino)disilane ([Me₂N]₂MeSi-SiMe[NMe₂]₂); 1,2-dimethyl-tetrakis(diethylamino)disilane ([Et₂N]₂MeSi-SiMe[NEt₂]₂); hexakis(methylamino)disilane ([MeHN]₃Si—Si[NHMe]₃); hexakis(ethylamino)disilane ([EtHN]₃Si—Si[NHEt]₃); hexakis(dimethylamino)disilazane (Me₂N—Si[NMe₂]₂—Si[NMe₂]₂—NMe₂), and the like.

### Silyl Amines

A silicon-containing precursor can include one or more optionally substituted silyl groups attached to a nitrogen atom, thereby providing a non-limiting silyl amine. In one embodiment, the precursor has a formula of (R″)_{3-y}N(SiR′₃)_{y}, wherein:
y is 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the silicon-containing reactant has a formula of (R′₃Si)_{y}(R″)_{2-y}N-L-N(R″)_{2-y}(SiR′₃)_{y}, wherein:
each y is, independently, 0, 1, or 2; L is a linker, such as a covalent bond, optionally substituted aliphatic, optionally substituted heteroaliphatic, optionally substituted aromatic, optionally substituted heteroaromatic, oxy (—O—), imino, or silyl; each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl,
optionally in which N-L-N, taken together, forms a multivalent heterocyclyl group.

In one instance, at least one y is not 0. In another embodiment, y can be 0 (e.g., if L includes a carbon atom or a heteroatom). In yet another embodiment, y is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂— and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃ or —SiR₂-L-SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl. L can be any useful linker (e.g., a covalent bond, optionally substituted alkylene, optionally substituted heteroalkylene, oxy, imino, silyl, or the like).

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The silicon-containing reactant can include at least one R″ group attached to the nitrogen atom. In one embodiment, the precursor has a formula of (R″)N(SiR′₃)₂ or (R″)₂N(SiR′₃), wherein R′ and R″ can be any described herein. In another embodiment, the precursor has a formula of (R″)₂N(SiH₃) or (R″)N(SiH₃)₂, wherein R″ can be any described herein. In particular embodiments, R′ is optionally substituted alkyl, amino, or alkoxy; and R″ is optionally substituted alkyl or amino, optionally wherein two R″ are taken together, with the nitrogen atom to which each are attached, to form a heterocyclyl.

Examples of suitable silicon-containing precursors include di(methylamino)silane (DMAS), di(ethylamino)silane (DEAS), di(propylamino)silane (DPAS), di(isopropylamino)silane (DIPAS), di(sec-butylamino)silane (DSBAS), bis-(t-butylamino)silane (BTBAS), and tris(dimethylamino)silane (TDMAS).

The silicon-containing reactant can include at least one hydrogen atom attached to the nitrogen atom. In one embodiment, the precursor has a formula of (H)N(SiR′₃)₂, wherein R′ can be any described herein. In another embodiment, the precursor has a formula of (H)N(SiR^{Ak}₃)₂, wherein R^{Ak} can be optionally substituted aliphatic, optionally substituted alkyl, optionally substituted alkenyl, or optionally substituted alkynyl.

The silicon-containing reactant can include three silicon atoms attached to the nitrogen atom. In one embodiment, the precursor has a formula of N(SiR′₃)₃, wherein R′ can be any described herein. In another embodiment, the precursor has a formula of N(SiH₃)(SiR′₃)₂, wherein R′ can be any described herein. In yet another embodiment, the precursor has a formula of N(SiH₃)(SiR^{Ak}₃)₂, wherein R^{Ak} can be optionally substituted aliphatic, optionally substituted alkyl, optionally substituted alkenyl, or optionally substituted alkynyl.

The silicon-containing reactant can have two or more nitrogen atoms, in which the precursor includes a N—N bond. In one instance, the precursor has a formula of (R′₃Si)₂N—N(SiR′₃)₂, wherein R′ can be any described herein.

A linker can be present between nitrogen atoms. In one instance, the precursor has a formula of (R′₃Si)(R″)N-L-N(R″)(SiR′₃) or (R′₃Si)₂N-L-N(SiR′₃)₂, wherein R′ and R″ can be any described herein. In some embodiments, L is a covalent bond, optionally substituted alkylene, optionally substituted heteroalkylene, —O—, —SiR₂—, or —Si—. In particular embodiments, at least one of R″ is not H. In another instance, the precursor has a formula of (H₃Si)(R″)N-L-N(R″)(SiH₃), wherein R″ can be any described herein.

The linker can include a silicon atom. In one instance, the precursor has a formula of (R′₃Si)₂N—SiR′₂—N(SiR′₃)₂, wherein R′ can be any described herein. In another instance, the precursor has a formula of (R′₃Si)(R″)N—SiR′₂—N(R″)(SiR′₃) or (R′₃Si)₂N—SiR′₂—N(R″)₂, wherein R′ and R″ can be any described herein.

The linker can include a SiH₂ group. In one instance, the precursor has a formula of (R′₃Si)₂N—SiH₂—N(SiR′₃)₂, wherein R′ can be any described herein. In another instance, the precursor has a formula of (R′₃Si)HN—SiH₂—NH(SiR′₃) or (R′₃Si)₂N—SiH₂—N(R″)₂, wherein R′ and R″ can be any described herein.

A plurality of nitrogen- and silicon-containing moieties may be present within the precursor. In one embodiment, the precursor has a formula of (R′₃Si)(R″)N—SiR′₂—N(R″)—SiR′₂—N(R″)(SiR′₃), wherein R′ and R″ can be any described herein.

Non-limiting precursors can include, e.g., 1,1,3,3-tetramethyldisilazane (NH[SiHMe₂]₂ or TMDS); 1,1,2,3,3-pentamethyldisilazane (NMe[SiHMe₂]₂); 1,1,1,3,3,3-hexamethyldisilazane (NH[SiMe₃]₂ or HMDS); heptamethyldisilazane (NMe[SiMe₃]₂); 1,1,1,3,3,3-hexamethyl-2-ethyldisilazane (NEt[SiMe₃]₂); 1,1,1,3,3,3-hexamethyl-2-isopropyldisilazane (NiPr[SiMe₃]₂); 1,1,1,3,3,3-hexaethyl-2-isopropyldisilazane (NiPr[SiEt₃]₂); 1,1,3,3-tetramethyl-2-isopropyl disilazane (NiPr[SiHMe₂]₂); 1,1,3,3-tetraethyl-2-isopropyldisilazane (NiPr [SiHEt₂]₂); 1,3-diethyltetramethyldisilazane (NH[SiMe₂Et]₂); 1,1,3,3-tetraethyldisilazane (NH[SiHEt₂]₂); 1,1,3,3-tetraethyl-2-methyldisilazane (NMe[SiHEt₂]₂); 1,1,1,3,3,3-hexaethyldisilazane (NH[SiEt₃]₂); 1,1,1,3,3,3-hexaethyl-2-methyldisilazane (NMe[SiEt₃]₂); 1,1,1,2,3,3,3-heptaethyldisilazane (NEt[SiEt₃]₂); 1,2,3-trimethyltrisilazane (N[SiH₂Me]₃); nonamethyltrisilazane (N[SiMe₃]₃); di-iso-propylsilylamine (NiPr₂[SiH₃]); diethylsilylamine (NEt₂[SiH₃]); diisopropylsilylamine (NiPr₂[SiH₃]); di-sec-butylsilylamine (NsBu₂[SiH₃]); di-tert-butylsilylamine (NtBu₂[SiH₃]); disilylmethylamine (NMe[SiH₃]₂); disilylethylamine (NEt[SiH₃]₂); disilylisopropylamine (NiPr[SiH₃]₂); disilyl-tert-butylamine (NtBu[SiH₃]₂); bis(trimethylsilyl) amine (NH[SiMe₃]₂); bis(triethylsilyl)amine (NH[SiEt₃]₂); and the like.

### Silazanes and Derivatives Thereof

A silicon-containing precursor can include one or more amino, silyl, and/or imino groups, thereby providing a silazane or a derivative thereof having one or more Si—N, N—Si—N, Si—N—Si, N—Si—Si, or N—Si—N—Si bonds. In one embodiment, the precursor has a formula of (R″)_{3-y}N(SiR′₂-L-SiR′₃)_{y}, wherein:
y is 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the silicon-containing reactant has a formula of (R″)_{3-y}N(SiR′₂-L-SiR′₂—NR″₂)_{y}, wherein y is 1, 2, or 3; and each of L, R′, and R″ can be any described herein.

In yet another embodiment, the silicon-containing reactant has a formula of (R″)_{3-y}N(SiR′₂-L-NR″₂)_{y}, wherein y is 1, 2, or 3; and each of L, R′, and R″ can be any described herein.

In one embodiment, the silicon-containing reactant has a formula of (R′)₄₋ₓSi(NR″-L-SiR′₃)ₓ, wherein:
x is 1, 2, 3, or 4;
L is a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the silicon-containing reactant has a formula of (R″2N)—(SiR′₂-L)_{z}-SiR′₃, wherein z is 1, 2, or 3; and each of L, R′, and R″ can be any described herein.

In some embodiments, L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃ or —SiR₂-L-SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl. L can be any useful linker (e.g., a covalent bond, optionally substituted alkylene, optionally substituted heteroalkylene, oxy, imino, silyl, or the like).

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The silicon-containing reactant can include one or more disilanyl groups and amino groups. In one embodiment, the precursor has a formula of R″₂N—SiR′₂—SiR′₃, wherein L, R′, and R″ can be any described herein. In other embodiments, the precursor has a formula of R″₂N—SiH₂—SiH₃, wherein R″ is any described herein. In another embodiment, the precursor has a formula of (R″)_{3-y}N—(SiR′₂—SiR′₃)_{y}, wherein y, R′, and R″ can be any described herein. In yet another embodiment, the precursor has a formula of (R″)_{3-y}N—(SiH₂—SiH₃)_{y}, wherein y and R″ can be any described herein.

The silicon-containing reactant can include a bivalent disilanyl group. In one embodiment, the precursor has a formula of R″₂N—SiR′₂—SiR′₂-L-NR″₂, wherein L, R′, and R″ can be any described herein. In another embodiment, the precursor has a formula of R″₂N—SiR′₂—SiR′₂—NR″₂, wherein R′ and R″ can be any described herein.

A linker L can be present between two silyl group. In one embodiment, the precursor has a formula of R″₂N—SiR′₂-L-SiR′₃ or R″N—(SiR′₂-L-SiR′₃)₂, wherein L, R′, and R″ can be any described herein. In another embodiment, the precursor has a formula of R″₂N—SiR′₂-L-SiR′₂—NR″₂, wherein L, R′, and R″ can be any described herein. In yet another embodiment, the precursor has a formula of (R″)_{3-y}N—(SiR′₂-L-SiH₃)_{y}, wherein y, L, R′, and R″ can be any described herein.

The silicon-containing reactant can include —SiH₃ as the silyl group. In one embodiment, the precursor has a formula of R″₂N—SiH₂—SiH₃, wherein R″ can be any described herein. In another embodiment, the precursor has a formula of (R″)N—(SiH₂-L-SiH₃)₂ or (R″)₂N—(SiH₂-L-SiH₃), wherein L and R″ can be any described herein.

The silicon-containing reactant can include a silyl-substituted amino group, such as, e.g., —NR″—SiR′₃, in which R′ and R″ can be any described herein. In one embodiment, the precursor has a formula of (R′)₄₋ₓSi(NR″—SiR′₃)ₓ or (R′)₄₋ₓSi(NH—SiR′₃)ₓ, wherein x is 1, 2, 3, or 4; and in which R′ and R″ can be any described herein. In another embodiment, the precursor has a formula of H₂Si(NR″—SiR′₃)₃, wherein R′ and R″ can be any described herein.

The silicon-containing reactant can include a bis-trisilylamino group, such as, e.g., —N(SiR′₃)₂ in which R′ can be any described herein. In one embodiment, the precursor has a formula of R″₂N—SiR′₂—N(SiR′₃)₂, in which R′ and R″ can be any described herein. In another embodiment, the precursor has a formula of R″₂N—SiH₂—N(SiH₃)₂, in which R′ can be any described herein. In yet another embodiment, the precursor has a formula of (R′₃Si)₂N—[SiR′₂—N(SiR′₃)]_{z}(SiR′₃), wherein z is 0, 1, 2, or 3; and in which R′ and R″ can be any described herein.

The silicon-containing reactant can include a linker L disposed between a silicon atom and a nitrogen atom. In one embodiment, the precursor has a formula of R″₂N—SiR′₂-L-NR″₂, wherein L, R′, and R″ can be any described herein.

The silicon-containing reactant can include a linker L disposed between two nitrogen atoms. In one embodiment, the precursor has a formula of R′₃Si—SiR′₂—NR″-L-NR″—SiR′₂—SiR′₃, wherein L, R′, and R″ can be any described herein.

The linker can include a silylimino group, such as, e.g., —N(SiR′₃)—, in which R′ can be any described herein. In one embodiment, the precursor has a formula of R″₂N—[SiR′₂—N(SiR′₃)]_{z}—SiR′₃ or R″₂N—[N(SiR′₃)]_{z}—SiR′₃, in which z is 1, 2, 3, or more; and wherein R′ and R″ can be any described herein.

The linker can include both a silyl group and an imino group. In one embodiment, the precursor has a formula of R″₂N—[SiR′₂—NR″ ]_{z}—SiR′₃, in which z is 1, 2, 3, or more; and wherein R′ and R″ can be any described herein.

Non-limiting silicon-containing reactants include, e.g., di-iso-propylaminodisilane ([iPr₂N]—SiH₂—SiH₃); di-sec-butylaminodisilane ([sBu₂N]—SiH₂—SiH₃); methylcyclohexylaminodisilane ([MeCyN]—SiH₂—SiH₃); methylphenylaminodisilane ([MePhN]—SiH₂—SiH₃); piperidinodisilane; 3,5-dimethylpiperidinodisilane; di-iso-propylaminotrisilylamine ([iPr₂N]—SiH₂—N[SiH₃]₂); diethylaminotrisilylamine ([Et₂N]—SiH₂—N[SiH₃]₂); iso-propylaminotrisilylamine ([iPrHN]—SiH₂—N[SiH₃]₂); and the like.

### Mixed Amines Including Silicon and Oxygen

A silicon-containing reactant can include one or more amino groups substituted with a silyl group, thereby providing a non-limiting mixed amine. In one embodiment, the precursor has a formula of (R″)_{3-y}N[Si(OR″′)ₓR′₃₋ₓ]y, wherein:
each of x and y is, independently, 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl; and
each R″′ is, independently, H, aliphatic, heteroaliphatic, aromatic, heteroaromatic, silyl, or silyloxy, in which any of these may be optionally substituted.
   Non-limiting examples of R′, R″, and R″′ are described herein, e.g., such as for amino silane, siloxane, silyl amine, or derivatives thereof.

The silicon-containing reactant can include any combination of R″ groups and silicon-containing groups. In one embodiment, the precursor has a formula of (R″)_{3-y}N[Si(OR^{Ak})ₓR^{Ak}₃₋ₓ]_{y} or (R^{Ak})_{3-y}N [Si(OR^{Ak})ₓR^{Ak}₃₋ₓ]_{y}, in which R″, x, and y is any described herein; and wherein R^{Ak} is H, optionally substituted aliphatic, or optionally substituted heteroaliphatic. In particular embodiments, R^{Ak} is H, optionally substituted alkyl, optionally substituted alkylene, or optionally substituted alkynyl. In other embodiments, the precursor has a formula of (R″)_{3-y}N [Si(OR^{Ak})ₓH₃₋ₓ]_{y} or (R″)_{3-y}N[Si(OR^{Ak})H(R′)]_{y}, in which R″, R′, x, and y is any described herein.

The silicon-containing reactant can include two silicon-containing groups. In one embodiment, the precursor has a formula of (R″)N[Si(OR^{Ak})ₓR^{Ak}₃₋ₓ]₂ or (R^{Ak})N[Si(OR^{Ak})ₓR^{Ak}₃₋ₓ]₂, in which R″, R^{Ak}, x, and y is any described herein. In particular embodiments, x is 1 or 2.

The silicon-containing reactant can include a hydrogen atom attached to the nitrogen atom. In one embodiment, the precursor has a formula of (H)_{3-y}N[Si(OR^{Ak})ₓR^{Ak}-x]_{y} or (H)_{3-y}N[Si(OR^{Ak})ₓH₃₋ₓ]_{y} or (H)_{3-y}N[Si(OR^{Ak})H(R^{Ak})]_{y}, in which R^{Ak}, x, and y is any described herein. In particular embodiments, x is 1 or 2.

Non-limiting silicon-containing reactant include, e.g., bis(dimethoxysilyl)amine (NH[Si(OMe)₂H]₂); bis(diethoxysilyl)amine (NH[Si(OEt)₂H]₂); N-iso-propylbis(diethoxysilyl)amine (NiPr[Si(OEt)₂H]₂); bis(methoxymethylsilyl)amine (NH[Si(OMe)MeH]₂); tris(dimethoxysilyl) amine (N[Si(OMe)₂H]₃); tris(methoxymethylsilyl)amine (N[Si(OMe)MeH]₃); tris(diethoxysilyl) amine (N[Si(OEt)₂H]₃); tris(trimethoxysilyl)amine (N[Si(OMe)₃]₃); and the like.

### Cyclic Silazanes

A silicon-containing reactant can include a cyclic group having one or more nitrogen atoms. In one embodiment, the precursor has a formula of [NR″—(SiR′₂)ₙ]_{z}, wherein:
z is 1, 2, 3, 4, 5, or more;
n is 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In one embodiment, the silicon-containing reactant has a formula of [NR″—(SiR′₂)ₙ-L-(SiR′₂)ₙ]_{z}, wherein:
z is 1, 2, 3, 4, 5, or more;
each n is, independently, 1, 2, or 3;
each L is, independently, a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the silicon-containing reactant has a formula of [NR″-L-NR″—(SiR′₂)ₙ]_{z}, wherein: z is 1, 2, 3, 4, 5, or more; each n is, independently, 1, 2, or 3; and in which R′ and R″ can be any described herein.

In yet another embodiment, the precursor has a formula of [L-(SiR′₂)ₙ]_{z}, wherein:
z is 1, 2, 3, 4, 5, or more; each n is, independently, 1, 2, or 3; L is imino (e.g., —NR—), optionally substituted aliphatic, optionally substituted heteroaliphatic, or combinations thereof; and in which R′ can be any described herein. In particular embodiments, if L does not include a heteroatom, then R′ includes one or more heteroatoms (e.g., nitrogen atoms).

In one embodiment, the silicon-containing reactant has a formula of

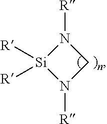

wherein R′ and R″ can be any described herein, and wherein n is 1, 2, 3, or 4.

In another embodiment, the silicon-containing reactant has a formula of

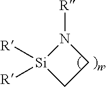

wherein R′ and R″ can be any described herein, and wherein n is 1, 2, 3, or 4.

In yet another embodiment, the silicon-containing reactant has a formula of

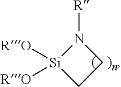

wherein R″ and R″′ can be any described herein, and wherein n is 1, 2, 3, or 4. In particular embodiments, each R″′ is, independently, H, aliphatic, heteroaliphatic, aromatic, heteroaromatic, silyl, or silyloxy, in which any of these may be optionally substituted.

In one embodiment, silicon-containing reactant has a formula of

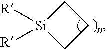

wherein R′ can include a heteroatom (e.g., a nitrogen atom, such as in optionally substituted amino, azido, isocyanato, or optionally substituted hydrazino), and wherein n is 1, 2, 3, or 4.

In some embodiments, L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In other embodiments, L is an optionally substituted alkylene, and at least one R′ includes an optionally substituted heteroaliphatic, optionally substituted amino, optionally substituted aliphatic-oxy, or optionally substituted alkoxy.

In some embodiments, each R′ is, independently, H, optionally substituted aliphatic, optionally substituted alkyl, optionally substituted alkenyl, optionally substituted alkynyl, optionally substituted aromatic, or optionally substituted aryl. In other embodiments, each R′ is, independently, optionally substituted heteroaliphatic, optionally substituted amino, or optionally substituted alkoxy.

In other embodiments, each R″ is, independently, H, optionally substituted aliphatic, optionally substituted alkyl, optionally substituted alkenyl, optionally substituted alkynyl, optionally substituted silyl, optionally substituted amino, optionally substituted aromatic, optionally substituted aryl, optionally substituted heteroaromatic, or optionally substituted heteroaryl.

Non-limiting silicon-containing reactants include 1,3,3-trimethylcyclodisilazane ([NH—SiMe₂][NH—SiMeH]); hexamethylcyclotrisilazane ([NH—SiMe₂]₃); octamethylcyclotetrasilazane ([NH—SiMe₂]₄); and the like.

### Amino Siloxane and Derivatives Thereof

A silicon-containing reactant can include siloxane or a derivative thereof and having one or more amino substitutions, thereby providing a siloxane or a derivative thereof having one or more Si—O, O—Si—O, or Si—O—Si bonds and having one or more —NR₂ substitutions. In one embodiment, the precursor has a formula of (R″)_{3-y}N[SiR′₂—(OSiR′₂)_{z}—R′]_{y}, wherein:
y is 1, 2, or 3;
z is 1, 2, 3, or more;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the silicon-containing reactant has a formula of (R″)_{3-y}N[(SiR′₂—O)_{z}—SiR′₃]_{y}, wherein R′, R″, y, and z can be any described herein.

The silicon-containing reactant can include an optionally substituted amino group with an optionally substituted silyl group. In one embodiment, the precursor has a formula of R″₂N—SiR′₂—(OSiR′₂)_{z}—R′ or R″₂N—SiR′₂—O—SiR′₃, wherein R′, R″, and z can be any described herein. In another embodiment, the precursor has a formula of R″₂N(SiR′₂—O)_{z}—SiR′₃, wherein R′, R″, and z can be any described herein.

The silicon-containing reactant can include two optionally substituted amino group. In one embodiment, the precursor has a formula of R″₂N—SiR′₂—(OSiR′₂)_{z}—NR″₂, wherein R′, R″, and z can be any described herein.

In some embodiments, R′ is H, optionally substituted aliphatic, optionally substituted alkyl, optionally substituted alkenyl, or optionally substituted alkynyl. In other embodiments, R″ is H, optionally substituted aliphatic, optionally substituted alkyl, optionally substituted alkenyl, or optionally substituted alkynyl. In particular embodiments, z is 1, 2, or 3.

Non-limiting silicon-containing reactant can include, e.g., 1-dimethylamino-pentamethyldisiloxane (Me₂N—SiMe₂-OSiMe₃); 1-diethylamino-pentamethyldisiloxane (Et₂N—SiMe₂-OSiMe₃); 1-ethylmethylamino-pentamethyldisiloxane (EtMeN-SiMe₂-OSiMe₃); 1,3-bis(dimethylamino) tetramethyldisiloxane (Me₂N—SiMe₂-OSiMe₂-NMe₂); 1-dimethylamino-heptamethyltrisiloxane (Me₂N—SiMe₂-[OSiMe₂]₂-Me); 1,5-bis(dimethylamino) hexamethyltrisiloxane (Me₂N—SiMe₂-[OSiMe₂]₂—NMe₂); and the like.

### Apparatus

The deposition methods described herein can be carried out in a variety of apparatuses. A suitable apparatus includes a process chamber, a substrate holder in the process chamber configured to hold the substrate in place during processing, an inlet to the process chamber for introducing one or more reactants and a plasma generating mechanism configured for generating a plasma in a process gas (directly in the proximity of the substrate or remotely).

Examples of suitable apparatuses include capacitively coupled plasma (CCP) and inductively coupled plasma (ICP) reactors. An example of a suitable apparatus is a Striker® reactor, produced by Lam Research Corp. of Fremont, CA.

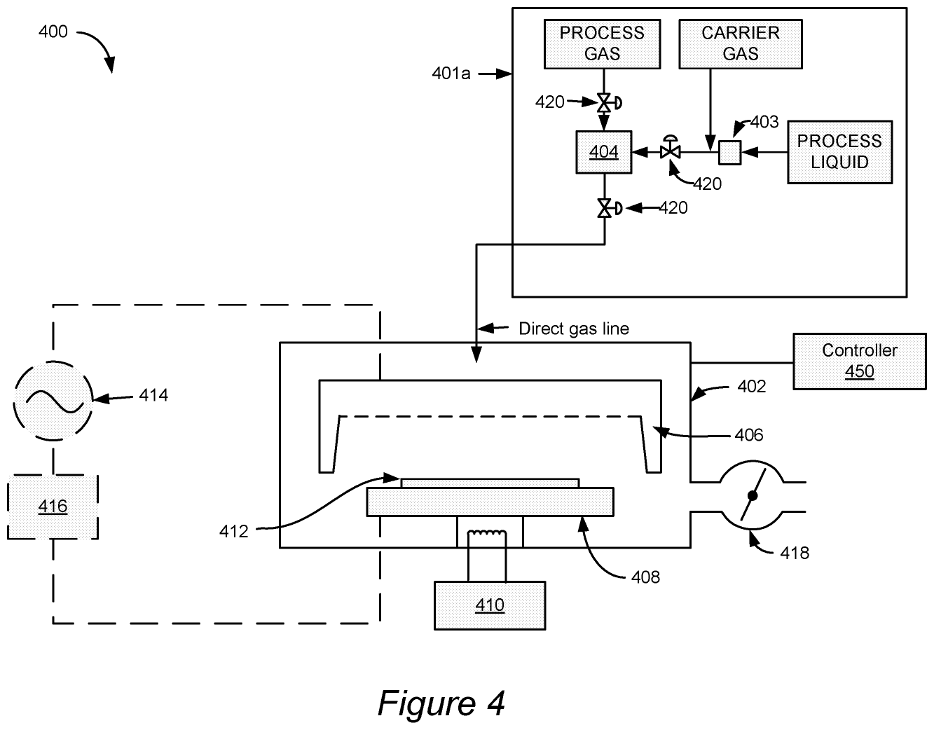

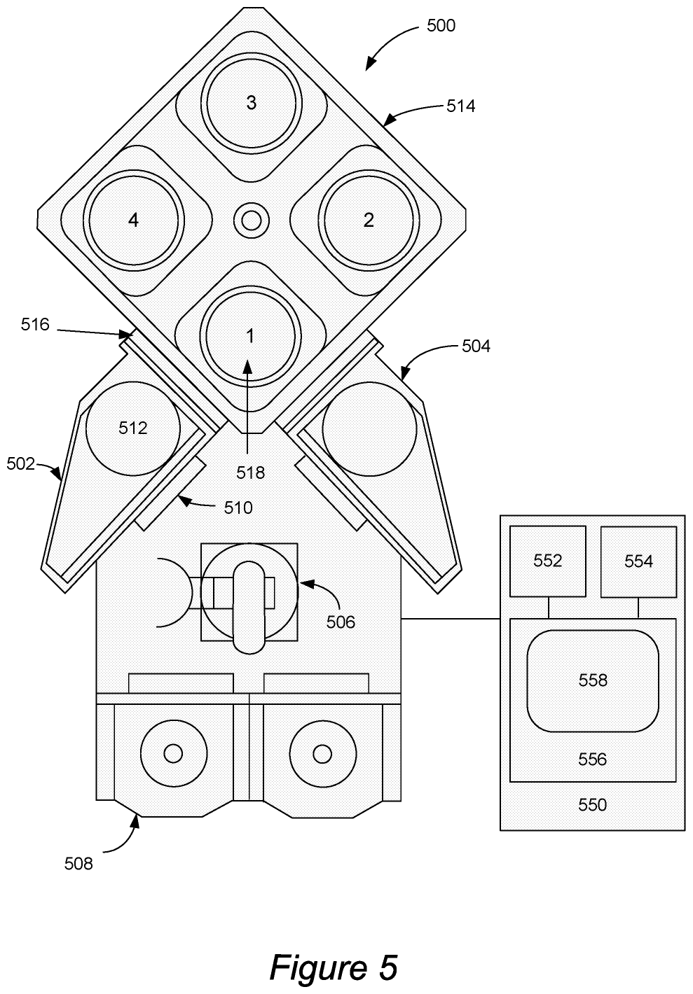

FIG. 4 depicts a schematic illustration of an embodiment of a plasma enhanced atomic layer deposition (PEALD) process station 400 having a process chamber body 402 for maintaining a low-pressure environment. A plurality of PEALD process stations 400 may be included in a common low pressure process tool environment. For example, FIG. 5 depicts an embodiment of a multi-station processing tool 500. In some embodiments, one or more hardware parameters of PEALD process station 400 including those discussed in detail above may be adjusted programmatically by one or more computer controllers 450.

PEALD process station 400 fluidly communicates with reactant delivery system 401a for delivering process gases to a distribution showerhead 406. Reactant delivery system 401a includes a mixing vessel 404 for blending and/or conditioning process gases, such as a silicon-containing precursor, or a carrier gas (e.g., argon or nitrogen), for delivery to showerhead 406. One or more mixing vessel inlet valves 420 may control introduction of process gases to mixing vessel 404. Nitrogen plasma may also be delivered to the showerhead 406 or may be generated in the PEALD process station 400.

As an example, the embodiment of FIG. 4 includes a vaporization point 403 for vaporizing liquid reactant to be supplied to the mixing vessel 404. In some embodiments, vaporization point 403 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 403 may be heat traced. In some examples, mixing vessel 404 may also be heat traced. In one non-limiting example, piping downstream of vaporization point 403 has an increasing temperature profile extending from approximately 100° C. to approximately 150° C. at mixing vessel 404.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 403. In one scenario, a liquid injector may be mounted directly to mixing vessel 404. In another scenario, a liquid injector may be mounted directly to showerhead 406.

In some embodiments, a liquid flow controller (LFC) upstream of vaporization point 403 may be provided for controlling a mass flow of liquid for vaporization and delivery to process station 400. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 406 distributes process gases toward substrate 412. In the embodiment shown in FIG. 4, the substrate 412 is located beneath showerhead 406 and is shown resting on a pedestal 408. Showerhead 406 may have any suitable shape, and may have any suitable number and arrangement of ports for distributing process gases to substrate 412.

In some embodiments, pedestal 408 may be raised or lowered to expose substrate 412 to a volume between the substrate 412 and the showerhead 406. It will be appreciated that, in some embodiments, pedestal height may be adjusted programmatically by a suitable computer controller 450.

In another scenario, adjusting a height of pedestal 408 may allow a plasma density to be varied during plasma activation cycles in the process in embodiments where a plasma is ignited. At the conclusion of the process phase, pedestal 408 may be lowered during another substrate transfer phase to allow removal of substrate 412 from pedestal 408.

In some embodiments, pedestal 408 may be temperature controlled via heater 410. In some embodiments, the pedestal 408 may be heated to maintain a temperature of between about 300-750° C., or in some embodiments, of between about 400-750° C., during deposition of silicon nitride films as described in disclosed embodiments. In some embodiments, the pedestal is set to maintain a temperature of between about 600° C. and about 700° C. during silicon nitride deposition.

Further, in some embodiments, pressure control for process station 400 may be provided by butterfly valve 418. As shown in the embodiment of FIG. 4, butterfly valve 418 throttles a vacuum provided by a downstream vacuum pump (not shown). However, in some embodiments, pressure control of process station 400 may also be adjusted by varying a flow rate of one or more gases introduced to the process station 400. In some embodiments the apparatus is configured to maintain a pressure of at least about 15 Torr, such as between about 15-30 torr during plasma treatment of an adsorbed silicon-containing precursor.

In some embodiments, a position of showerhead 406 may be adjusted relative to pedestal 408 to vary a volume between the substrate 412 and the showerhead 406. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers 450.

In some embodiments, showerhead 406 and pedestal 408 electrically communicate with a radio frequency (RF) power supply 414 and matching network 416 for powering a plasma. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are included above. Likewise, RF power supply 414 may provide RF power of any suitable frequency. In some embodiments, RF power supply 414 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 2.45 GHz, or greater than about 13.56 MHz, or greater than 27 MHz, or greater than 40 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 450 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, the controller may include program instructions for causing all of the steps of the methods provided herein. For example, the controller may include program instructions for causing delivery of the silicon-containing reactant to the process chamber in a first recipe phase; causing purging of the process chamber in a second recipe phase; causing treatment of the substrate with a plasma formed in a process gas comprising N2 at a pressure of between about 15 torr and about 30 torr in a third recipe, and causing purging of the process chamber in a fourth recipe.

As described above, one or more process stations may be included in a multi-station processing tool. FIG. 5 shows a schematic view of an embodiment of a multi-station processing tool 500 with an inbound load lock 502 and an outbound load lock 504, either or both of which may include a remote plasma source. A robot 506 at atmospheric pressure is configured to move wafers from a cassette loaded through a pod 508 into inbound load lock 502 via an atmospheric port 510. A wafer is placed by the robot 506 on a pedestal 512 in the inbound load lock 502, the atmospheric port 510 is closed, and the load lock is pumped down. Where the inbound load lock 502 includes a remote plasma source, the wafer may be exposed to a remote plasma treatment in the load lock prior to being introduced into a processing chamber 514. Further, the wafer also may be heated in the inbound load lock 502 as well, for example, to remove moisture and adsorbed gases. Next, a chamber transport port 516 to processing chamber 514 is opened, and another robot (not shown) places the wafer into the reactor on a pedestal of a first station shown in the reactor for processing. While the embodiment depicted in FIG. 5 includes load locks, it will be appreciated that, in some embodiments, direct entry of a wafer into a process station may be provided.

The depicted processing chamber 514 includes four process stations, numbered from 1 to 4 in the embodiment shown in FIG. 5. Each station has a heated pedestal (shown at 518 for station 1), and gas line inlets. It will be appreciated that in some embodiments, each process station may have different or multiple purposes. For example, in some embodiments, a process station may be switchable between an ALD and plasma-enhanced ALD process mode. Additionally or alternatively, in some embodiments, processing chamber 514 may include one or more matched pairs of ALD and plasma-enhanced ALD process stations. While the depicted processing chamber 514 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 5 depicts an embodiment of a wafer handling system 590 for transferring wafers within processing chamber 514. In some embodiments, wafer handling system 590 may transfer wafers between various process stations and/or between a process station and a load lock. It will be appreciated that any suitable wafer handling system may be employed. Non-limiting examples include wafer carousels and wafer handling robots. FIG. 5 also depicts an embodiment of a system controller 550 employed to control process conditions and hardware states of process tool 500. System controller 550 may include one or more memory devices 556, one or more mass storage devices 554, and one or more processors 552. Processor 552 may include a CPU or computer, analog, and/or digital input/output connections, stepper motor controller boards, etc.

In some embodiments, system controller 550 controls all of the activities of process tool 500. System controller 550 executes system control software 558 stored in mass storage device 554, loaded into memory device 556, and executed on processor 552. Alternatively, the control logic may be hard coded in the controller 550. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 558 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 500. System control software 558 may be configured in any suitable way. For example, various process tool component subroutines or control objects may be written to control operation of the process tool components used to carry out various process tool processes. System control software 558 may be coded in any suitable computer readable programming language.

In some embodiments, system control software 558 may include input/output control (IOC) sequencing instructions for controlling the various parameters described above. Other computer software and/or programs stored on mass storage device 554 and/or memory device 556 associated with system controller 550 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 518 and to control the spacing between the substrate and other parts of process tool 500.

A process gas control program may include code for controlling gas composition (e.g., silicon precursor gases, and nitrogen-containing gases, carrier gases and purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 550. The user interface may include a display screen, graphical software displays of the apparatus and/or process conditions, and user input devices such as pointing devices, keyboards, touch screens, microphones, etc.

In some embodiments, parameters adjusted by system controller 550 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 550 from various process tool sensors. The signals for controlling the process may be output on the analog and digital output connections of process tool 500. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 550 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 550 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 550.

In some implementations, the system controller 550 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 550, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 550 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 550 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 550, in some implementations, may be a part of or coupled to a computer that is integrated with, coupled to the system, otherwise networked to the system, or a combination thereof. For example, the system controller 550 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 550 receives instructions in the form of data, which specify parameters for each of the processing steps to be performed during one or more operations. It should be understood that the parameters may be specific to the type of process to be performed and the type of tool that the system controller 550 is configured to interface with or control. Thus, as described above, the system controller 550 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers. As noted above, depending on the process step or steps to be performed by the tool, the system controller 550 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### EXPERIMENTAL RESULTS

### Example 1

Silicon nitride was deposited on a substrate having an exposed silicon layer (silicon fins) with a plurality of recessed features having 6:1 aspect ratio, by conducting multiple deposition cycles in one process chamber. Deposition was performed at 650° C. and a pressure of 18 Torr throughout the deposition process. DIPAS was used as the silicon-containing precursor. Each deposition cycle included the following steps:
(1) exposure of the substrate to DIPAS in an absence of plasma (provided in a mixture with argon at a total flow rate of 1,500 sccm);
(2) process chamber purge with a mixture of nitrogen and argon (provided at a flow rate of 20 slm each);
(3) treatment of the substrate with a plasma (using RF frequency of 13.56 MHz, and power density of 1.77 W/cm²) formed in a process gas, where the process gas is a mixture of nitrogen (provided at a flow rate of 2,000 sccm) and argon (provided at a flow rate of 18 slm);
(4) process chamber purge with a mixture of nitrogen and argon (provided at a flow rate of 20 slm each).

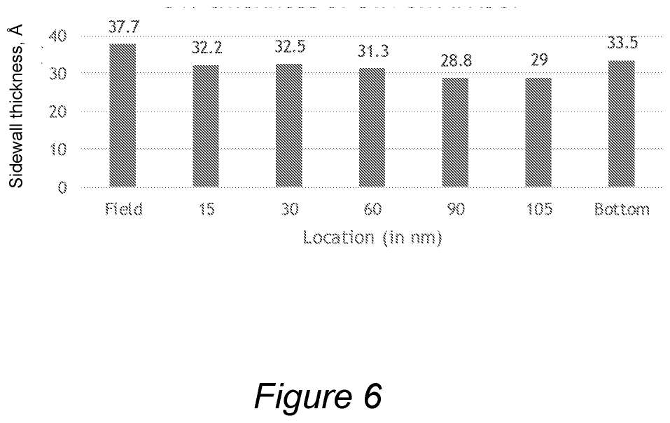

The thickness of deposited silicon nitride was measured on a recessed feature sidewall at different feature depths. FIG. 6 illustrates the measured thickness (in Å) at different depths in the feature. It can be seen that sidewall thickness has very small variation ranging from 32.2 Å at the depth of 15 nm to 29 Å at the depth of 105 nm. The conformality measured for this deposition was about 90% illustrating that deposition at a relatively high pressure of 18 Torr in combination with the use of lowered N₂ content (10% of the total flow rate) during the conversion step provides excellent conformality.

### Example 2

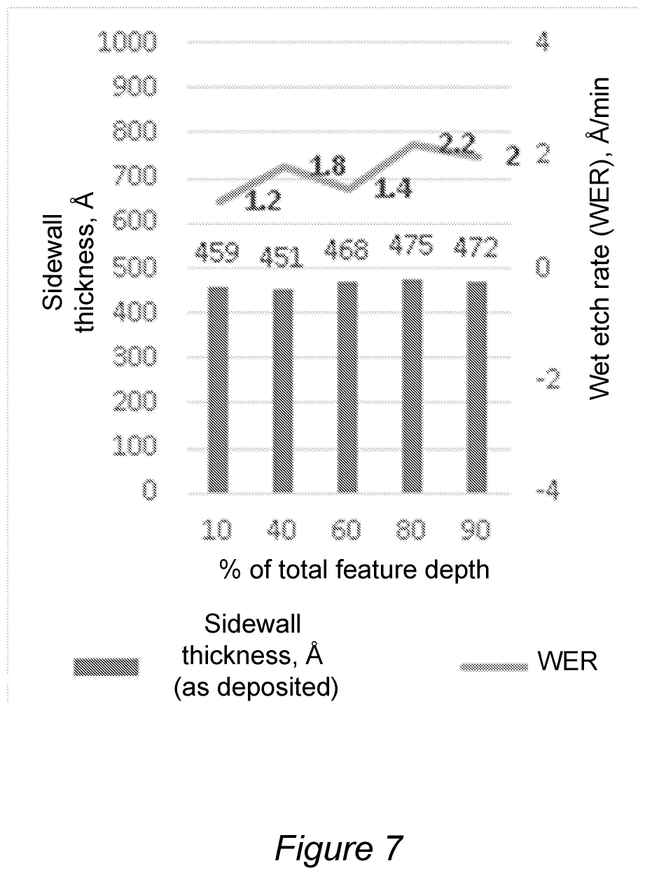

Silicon nitride was deposited on a substrate having recessed features with 30:1 aspect ratio under the same process conditions as in deposition of Example 2. Thickness of the deposited silicon nitride and WER were measured at different depths on the sidewalls. The results are shown in FIG. 7, which illustrates that WER was consistently less than 3 Å/minute. The smallest thickness was 459 Å, and the largest thickness was 472 Å. Conformality for this deposition was about 100% This example illustrates that high conformality and low WER at different feature depth points can be simultaneously achieved by provided methods.

### Example 3

Silicon nitride was deposited in recessed features having 30:1 aspect ratio using the method disclosed in Example 1 with the following variation:
Curve (a) (Comparative): conversion step was conducted at 2 Torr; nitrogen content in the process gas during conversion step was 50%
Curve (b): conversion step was conducted at 18 Torr; nitrogen content in the process gas during conversion step was 50%
Curve (c): conversion step was conducted at 18 Torr; nitrogen content in the process gas during conversion step was 5%

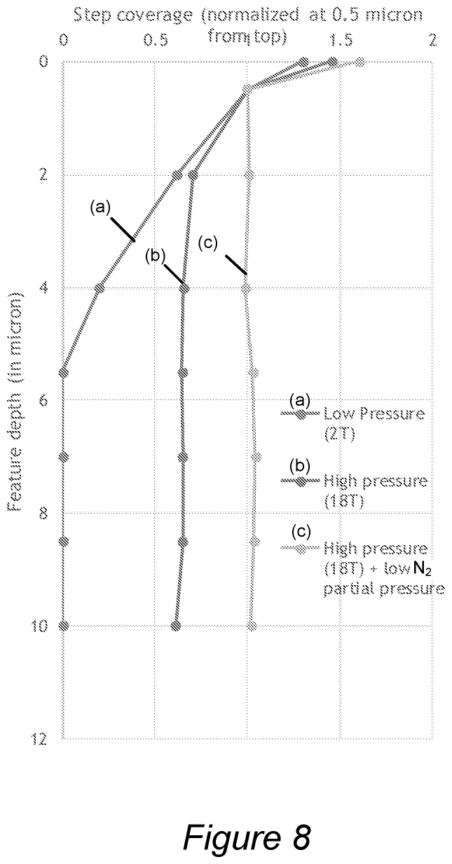

FIG. 8 is a plot illustrating step coverage as a function of feature depth for different process conditions. It can be seen that in a comparative example (curve (a)) there is no silicon nitride deposited on the sidewall in lower part of the feature. This illustrates the dramatic effect of pressure. Curve (b) illustrates a significant improvement in step coverage due to an increase in pressure from 2 Torr to 18 Torr. Curve (c) illustrates further improvement in step coverage due to lowering of nitrogen content from 50% to 5%.

### Example 4

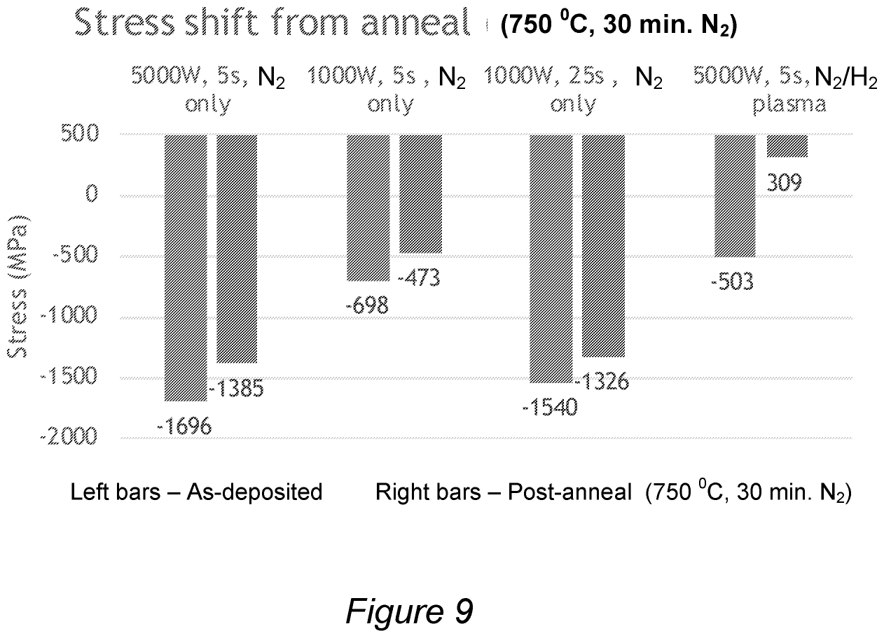

Silicon nitride films were annealed at 750° C. in a nitrogen atmosphere for 30 minutes. A significant improvement in WER was obtained. For example, films that had WER of greater than 5 Å/minute as-deposited, all exhibited WER of less than 4 Å/minute, with one film exhibiting more than a five fold decrease in WER after an anneal. In addition, anneal was found to reduce stress values of deposited films. FIG. 9 shows stress values for different deposited silicon nitride films before and after an anneal. It is noted that for all films absolute value of stress decreased.

1. A method of depositing a silicon nitride layer on a semiconductor substrate, the method comprising:
(a) in a process chamber, exposing the semiconductor substrate to a halogen-free silicon-containing precursor, wherein the silicon-containing precursor further includes at least one nitrogen (N) atom, to form an adsorbed layer of the silicon-containing precursor on the semiconductor substrate; and
(b) in the same process chamber, treating the semiconductor substrate with a plasma formed in a process gas comprising nitrogen (N₂) to convert the adsorbed layer of the silicon-containing precursor to silicon nitride, wherein the conversion of the adsorbed layer of the silicon-containing precursor to silicon nitride is performed at a temperature of between about 300° C. and about 750° C. and a pressure of at least about 15 Torr.

2. The method of claim 1, wherein the semiconductor substrate comprises a recessed feature, and wherein the silicon nitride layer is deposited in the recessed feature with a conformality of at least about 80%.

3. The method of claim 1, wherein the semiconductor substrate comprises a recessed feature, wherein the silicon nitride layer is deposited in the recessed feature with a conformality of at least about 80%, and wherein the deposited silicon nitride has a wet etch rate (WER) in 100:1 hydrofluoric acid of less than about 3 Å/minute.

4. The method of claim 1, wherein the semiconductor substrate comprises a recessed feature, wherein the silicon nitride layer is deposited in the recessed feature with a conformality of at least 90%, and wherein the deposited silicon nitride has a wet etch rate (WER) in 100:1 hydrofluoric acid of less than about 2 Å/minute.

5. The method of claim 1, wherein the conversion of the adsorbed layer of the silicon-containing precursor to silicon nitride is performed at a temperature of between about 400° C. and about 750° C. and a pressure of between about 15 Torr and about 30 Torr.

6. The method of claim 1, wherein the process gas further includes a noble gas, and wherein N₂ content in the process gas is less than about 10% by volume.

7. The method of claim 1, wherein the process gas further includes a noble gas, and wherein N₂ content in the process gas is less than about 5% by volume.

8. The method of claim 1, wherein the deposited silicon nitride is substantially hydrogen-free evidenced by an absence of Si—H and N—H peaks on an infrared (IR) spectrum.

9. The method of claim 1, further comprising repeating steps (a)-(b) to perform at least 100 deposition cycles.

10. The method of claim 1, further comprising purging the process chamber to remove the unadsorbed silicon-containing precursor between (a) and (b).

11. The method of claim 1, wherein the semiconductor substrate comprises a recessed feature with an aspect ratio of at least 5:1, and wherein the silicon nitride is deposited conformally to a thickness of at least 100 Å.

12. The method of claim 1, further comprising repeating steps (a)-(b) to form a completed silicon nitride layer; and annealing the completed silicon nitride layer by exposing the semiconductor substrate to N₂ in an absence of plasma at a temperature of at least 700° C., wherein the annealing reduces absolute value of stress of silicon nitride.

13. The method of claim 1, wherein the halogen-free silicon-containing precursor is selected from the group consisting of di(methylamino)silane (DMAS), di(ethylamino)silane (DEAS), di(propylamino)silane (DPAS), di(isopropylamino)silane (DIPAS), di(sec-butylamino)silane (DSBAS), bis-(t-butylamino)silane (BTBAS), and tris(dimethylamino)silane (TDMAS).

14. The method of claim 1, further comprising the steps of:
applying photoresist to the semiconductor substrate;
exposing the photoresist to light;
patterning the photoresist and transferring the pattern to the semiconductor substrate;
and selectively removing the photoresist from the semiconductor substrate.

15. An apparatus for processing a substrate, the apparatus comprising:
(a) a process chamber configured for housing the substrate, wherein the process chamber includes a substrate holder configured to hold the substrate and an inlet configured to introduce one or more reactants to the process chamber;
(b) a mechanism for generating a plasma; and
(c) a controller comprising program instructions configured to effect deposition of a silicon nitride layer on the substrate by causing:
(i) in the process chamber, exposing the substrate to a halogen-free silicon-containing precursor, wherein the silicon-containing precursor further includes at least one nitrogen (N) atom, to form an adsorbed layer of the silicon-containing precursor on the substrate; and
(ii) in the same process chamber, treating the substrate with a plasma formed in a process gas comprising nitrogen (N₂) to convert the adsorbed layer of the silicon-containing precursor to silicon nitride, wherein the conversion of the adsorbed layer of the silicon-containing precursor to silicon nitride is performed at a temperature of between about 300° C. and about 750° C. and a pressure of at least about 15 Torr.

16. The apparatus of claim 15, wherein the pressure is between about 15 Torr and about 30 Torr.

17. The apparatus of claim 15, wherein the temperature is between about 400° C. and about 750° C.

18. The apparatus of claim 15, wherein the program instructions comprise instructions configured to repeat steps (i)-(ii) to perform at least 100 deposition cycles.

19. The apparatus of claim 15, wherein the halogen-free silicon-containing precursor is selected from the group consisting of di(methylamino)silane (DMAS), di(ethylamino)silane (DEAS), di(propylamino)silane (DPAS), di(isopropylamino)silane (DIPAS), di(sec-butylamino)silane (DSBAS), bis-(t-butylamino)silane (BTBAS), and tris(dimethylamino)silane (TDMAS).

20. The apparatus of claim 15, wherein the program instructions are configured to cause conformal deposition of the silicon nitride in a recessed feature with a conformality of at least about 80%.

21. (canceled)

22. A method of depositing a silicon nitride layer on a semiconductor substrate, the method comprising:
(a) in a process chamber, exposing the semiconductor substrate to a halogen-free silicon-containing precursor, wherein the silicon-containing precursor further includes at least one nitrogen (N) atom, to form an adsorbed layer of the silicon-containing precursor on the semiconductor substrate; and
(b) in the same process chamber, treating the semiconductor substrate with a plasma formed in a process gas comprising nitrogen (N₂) to convert the adsorbed layer of the silicon-containing precursor to silicon nitride, wherein the conversion of the adsorbed layer of the silicon-containing precursor to silicon nitride is performed at a temperature of between about 300° C. and about 750° C. and wherein the content of N₂ in the process gas is less than about 10%.
